(19) United States
(12) Patent Application Publication
(10) Pub. No.: US 2003/0008464 A1
(43) Pub. Date: Jan. 9, 2003

(54) Method for forming shallow retrograde wells in semiconductor device and shallow retrograde wells formed thereby

(75) Inventors: Yong-cheol Oh, Kyungki-do (KR); Dong-ho Shin, Seoul (KR); Kyu-whan Chung, Seoul (KR)

Correspondence Address: David A. Jakopin, PILLSBURY WINTHROP LLP, 1600 Tysons Boulevard, McLean, VA, 22102, US

(73) Assignee: Samsung Electronics Co., Ltd., Republic of Korea

(21) Appl. No.: 10/215,338

(22) Filed: Aug. 7, 2002

Related U.S. Application Data
(62) Division of application No. 09/524,513, filed on Mar. 13, 2000.
Application No. 09/524,513 is a continuation of application No. 08/652,004, filed on May 23, 1996, now abandoned.

(30) Foreign Application Priority Data
May 29, 1995 (KR) 95-13691

(51) Int. Cl. H01L 21/336

(52) U.S. Cl. 438/289

(57) ABSTRACT

A well ion-implantation process using an energy level equal to or lower than 400 KeV, instead of an energy level equal to or greater than 800 KeV, forms a well which functions as both a punchthrough stopper and a channel stopper and has few differences as compared to that of a device manufactured according to a conventional method, and, therefore, facilitates to simplify processes and enhance production without lowering the operational characteristics and reliability of a semiconductor device.

### BACKGROUND OF THE INVENTION

The present invention relates to a method for forming wells in a high density semiconductor device, and more particularly to a method for effectively forming wells in a semiconductor device by eliminating a high-energy ion-implantation process.

Conventional methods for forming a well in a high integration semiconductor device can be greatly divided into two types as follows.

The first method is to form a well which has a doping profile of uniform density by diffusing ion implanted dopant to an appropriate depth at high temperatures for an extended period of time. This type of well is called a diffused well due to diffusion of impurities.

The improved process of a diffused well with respect to process simplification is disclosed in U.S. Pat. No. 4,889,825, entitled “High/Low Doping Profile for Twin Well Process” by Louis et al. This is a method for simplifying a photo mask process for a plurality of ion-implantation processes, for example, a well ion-implantation process, a field ion-implantation process, a channel ion-implantation process, and a counter doping ion-implantation process. However, this method also requires a diffusion process at high temperatures and for an extended period of time, and accordingly has various problems.

The second method is to simplify processes by eliminating a process of heat treatment from the aforesaid diffused well processes, wherein a retrograde well using a high-energy ion-implantation process is proposed. The retrograde well shows a peak value of impurities concentration at a particular depth inside a silicon substrate. When the retrograde well is adjacent to the surface of the substrate, impurities concentration falls.

Methods for forming the retrograde well are disclosed in U.S. Pat. No. 4,633,289, entitled “Latchup Immune, Multiple Retrograde Well High Density CMOS FET”, and in a paper written by Toshiyuki Nishihara et al in IEDM88, pp.100-103, 1988.

Referring to FIGS. 1A through 1C, a conventional method for forming a retrograde well can be described as follows.

First, field oxide film 12 is formed on a semiconductor substrate 10 through a conventional device isolation process as shown in FIG. 1A. Next, referring to FIG. 1B, a well of a first conductivity type 14 is formed by well implantation, a field implant region 16 is formed by field ion-implantation, and a channel implant region 18 is formed by channel ion-implantation, all of which are formed by using predetermined mask pattern 13. Subsequently, referring to FIG. 1C, a well of a second conductivity type 24, a field implant region 26, and a channel implant region 28 are formed by using mask pattern 23 in the same manner as those in FIG. 1C, thereby forming a twin-well.

The graph in FIG. 2 is a doping profile showing the impurities concentration corresponding to the distance from the surface of a retrograde well formed through the aforesaid processes.

Referring to FIG. 2, a retrograde well of a P-well shows the impurities concentration at W where well ion-implantation of boron is performed at a high-energy level of approximately 700˜800 KeV, and at F where field ion-implantation of boron is performed at an approximately 130˜300 KeV. Point C indicates the impurities concentration at the depth where channel ion-implantation of boron fluoride (BF₂) is performed, for controlling the threshold voltage of a metal oxide silicon (MOS) transistor, at an energy level of approximately 40˜60 KeV. In the case of an N-well, after field ion-implantation, a process of high concentration ion-implantation is additionally performed so as to enhance the punchthrough characteristics of a PMOS transistor.

In the retrograde well processes, the well ion-implantation W restrains latchup and soft errors; and the field ion-implantation F not only determines device isolation characteristics but also has an effect on the active region in which transistors are formed, accordingly leading to a change in the electrical characteristics of transistors.

This retrograde well formed by high-energy ion-implantation serves to reduce process costs by eliminating the diffusion process at high temperatures and for an extended period of time, and further enhances the electrical characteristics of a device by restraining latchup and soft errors. However, these are poor advantages with respect to the increased production costs the process hours required in the manufacturing of a high-energy ion-implantation device.

The higher integration of the device leads to more manufacturing complications, thereby requiring more hours for the manufacturing process. A retrograde well process, which is derived from the conventional diffused well process, applied to a well formation process of 16M DRAM, accordingly shortens process hours. However, it takes about 62 days in the manufacturing of the 16M DRAM.

Therefore, the present invention proposes an advanced well process for shortening the process hours and enhancing production through process simplification, which facilitates in maintaining a balance in the characteristics and yield rate of a device by optimizing the retrograde well process of a 16M DRAM.

### SUMMARY OF THE INVENTION

It is an object of the present invention to provide a method for forming a well in a semiconductor device which simplifies processes and enhances production without lowering the operational characteristics of a semiconductor device and the reliability thereof.

To accomplish the above object of the present invention, there is provided a method for forming a well in a high integrated semiconductor device without performing a high-energy well ion-implantation process wherein wells for forming transistors of a predetermined conductivity type are formed by a field ion-implantation process functioning as both a punchthrough stopper and a channel stopper.

Preferably, the method for forming wells of a second conductivity type, in which MOS transistors having a channel of a first conductivity type are to be formed, uses a field ion-implantation process performing both the functions of a punchthrough stopper and a channel stopper without a high-energy well ion-implantation process, and performs an ion-implantation process so that a well region formed by the field ion-implantation process has a depth if approximately 1.0 μm or less.

To accomplish the above object of the present invention, there is provided a method for forming a well in a complementary MOS (hereinafter called a CMOS) comprising the steps of: preparing a semiconductor substrate of a second conductivity type; forming a field oxide film for limiting the active region of the semiconductor substrate; forming a mask pattern on one side of the active region isolated by the field oxide film; forming a well of a first conductivity type wherein a field ion-implantation process is performed by ion-implantation at an energy level and dose selected for functioning as both a punchthrough stopper and a channel stopper, thereby forming transistors having the same type of channel as the substrate; and forming a well of a second conductivity type wherein a field ion-implantation process is performed using a mask having an opposite pattern to the mask used in the previous step and using a selected ion-implantation energy level, a selected dose, and a selected dopant without a high-energy ion-implantation process for retrograde well peak, thereby forming transistors having a channel of the conductivity type opposite to that of the substrate.

Preferably, the semiconductor substrate consists of silicon of orientation (100), impurities of the first conductivity type consists of phosphorus or arsenic, and impurities of the second conductivity type consists of boron. Here, it is preferable to form well regions of the first and second type within approximately 1.0 μm deep from the surface of the semiconductor substrate.

Further, to form the wells of the first conductivity type, it is preferable to have ranges of the selected-energy level between 350˜400 KeV and the selected dose between 7.0E12˜1.0E13 ions/cm².

Meanwhile, to form the well of the second conductivity type, it is possible to use an energy level between 110˜160 KeV and a dose between 3.0E12˜5.0E12 ions/cm².

According to conventional methods, a retrograde well had been formed by implementing a plurality of ion-implantation processes, for example: processes of well ion-implantation for deep well peak; field ion-implantation for enhancing a characteristic of device isolation; ion-implantation in forming a well for stopping punchthrough having a conductivity type opposite the substrate; and channel ion-implantation for controlling threshold voltage Vₜₕ, particularly in which the ion-implantation process had used a high-energy level of more than 800 KeV. However, according to the present invention, wells which perform functions of both a punchthrough stopper and a channel stopper can be formed by implementing only a field ion-implantation process using an energy level of less than 400 KeV. Furthermore, in a test of a device produced by the improved well process according to the present invention, it was revealed that there was little difference in the reliability of this device and that of a “normal” device manufactured by the conventional method. Therefore, it is possible to simplify processes and to enhance production without lowering the operational characteristics of a device and the reliability thereof.

### BRIEF DESCRIPTION OF THE DRAWINGS

The above objects and advantages of the present invention will become more apparent by describing in detail a preferred embodiment thereof with reference to the attached drawings in which:

FIGS. 1A, 1B and 1C are cross-sectional views of for illustrating the processes used in a method of forming a conventional retrograde well;

FIG. 2 is a doping profile showing impurities concentration corresponding to the distance from the surface of a conventional retrograde well;

FIGS. 3A through 3D are cross-sectional views illustrating the processes wherein an improved well process according to the present invention is applied to a CMOS device;

FIG. 4A is a doping profile showing impurities concentration corresponding to the distance from the surface of a well according to the present invention;

FIG. 5 is a graph comparing and analyzing a body effect of P-MOS transistors produced by the conventional method and the present invention.

FIG. 6 is a graph comparing and analyzing a body effect of N-MOS transistors produced by the conventional method and the present invention.

### DETAILED DESCRIPTION OF THE INVENTION

An improved method for forming a well according to the present invention proposes to obtain the same characteristics as those of the retrograde well by simplifying the complicated manufacturing process, and can be particularly applied to the manufacturing of high density CMOS.

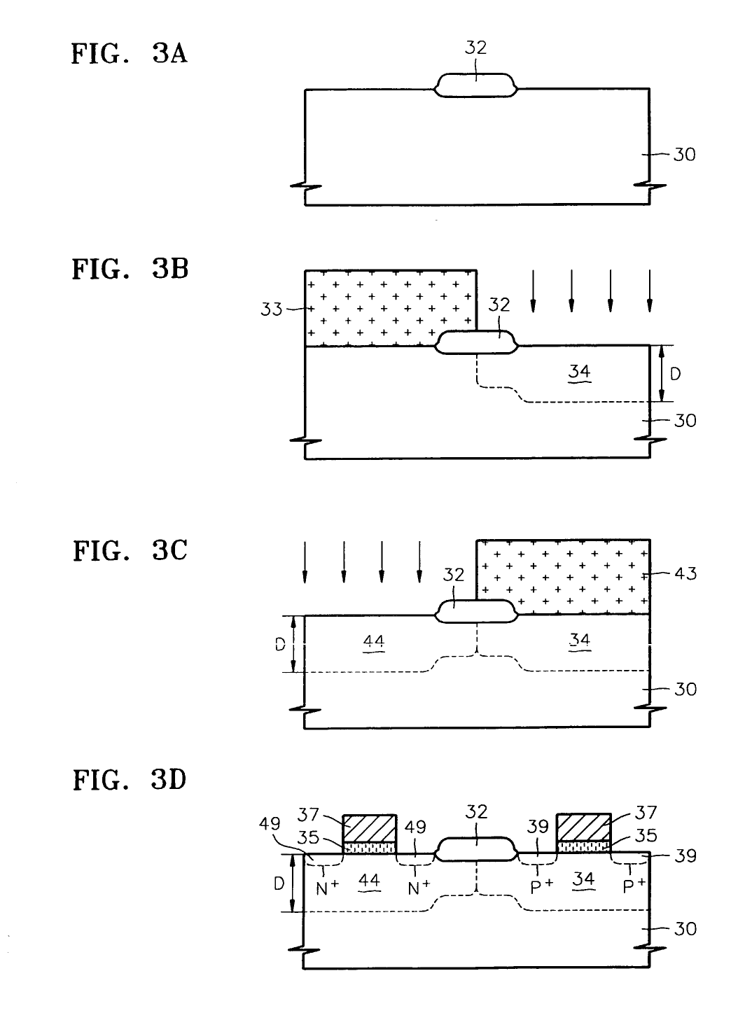

FIGS. 3A through 3D are cross-sectional views in turn illustrating the processes wherein the method for forming a well according to the present invention is applied to a CMOS having twin wells.

FIG. 3A shows a step of forming a field oxide film 32 for limitting the active region on a prepared semiconductor substrate 30. Semiconductor substrate 30 uses P-type silicon doped with boron at a concentration of 1.5×10¹⁵ cm⁻³ and a crystal orientation is (100). It is preferable to form field oxide film 32 to a thickness of approximately 4,500 Å using the conventional selective poly oxidation method (SEPOX). In order to eliminate a white ribbon phenomenon from being generated in forming field oxide film 32, a secondary sacrificial oxide film of thickness 500 Å can be formed at the surface of substrate 30 by thinly oxidizing it through thermal oxidation, which is not shown in FIG. 3A. Further, field oxide film 30 can also be formed using the conventional local oxidation of silicon method (LOCOS).

FIG. 3B shows a step of forming N-well 34 wherein a P-field ion-implantation process is performed by using mask pattern 33.

First, mask pattern 33 is formed on an active region of one side isolated by field oxide film 32. For example, photoresist is coated on the whole surface of substrate 30, and then exposed and developed, thereby forming first photoresist pattern 33 on a region of substrate 30 leaving the region expoaed where N-well 34 is to be formed.

Next, a P-field ion-implantation process is performed at a predetermined ion-implantation energy and dose, with first photoresist pattern 33 as a mask. Here, the ion-implantation energy and dose are selected so as to simultaneously perform functions of both a punchthrough stopper and a channel stopper without lower the latchup characteristic.

An improved N-well formation process according to the present invention makes it easier to control the depth (D) of the P-field ion-implantation region 34 of a well region within 1.0 μm, with an energy level in the range of approximately 350˜400 KeV with an impurity concentration and dose in the range of 7.0E12˜1.0E13 ions/cm² without lowering characteristics.

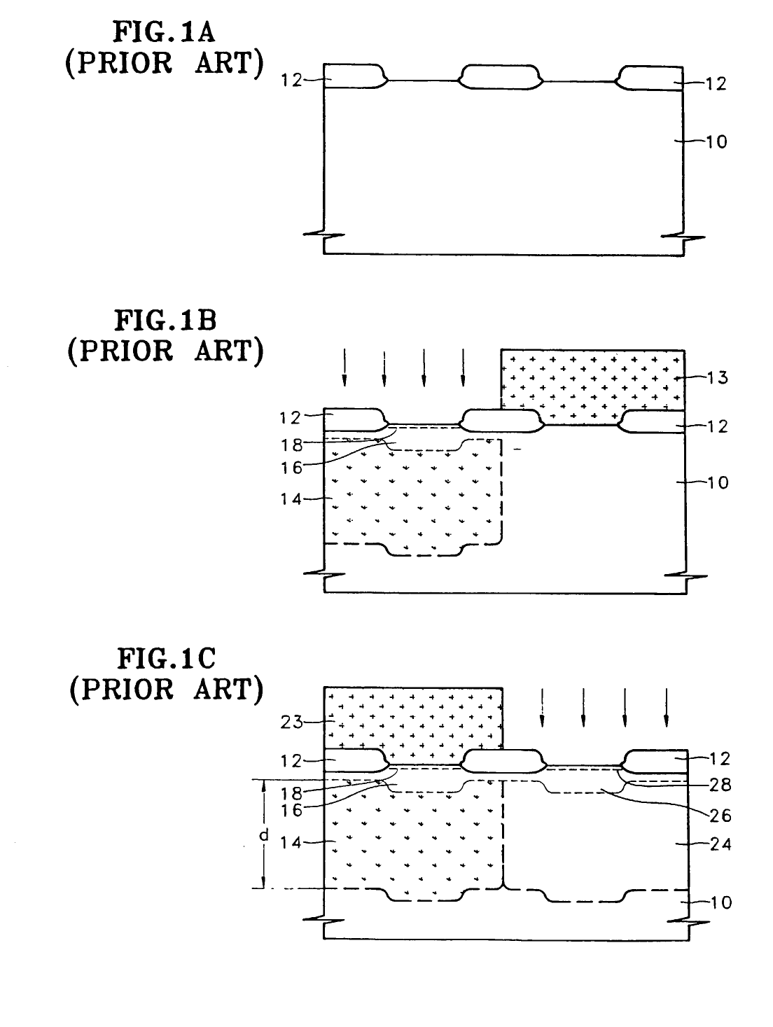

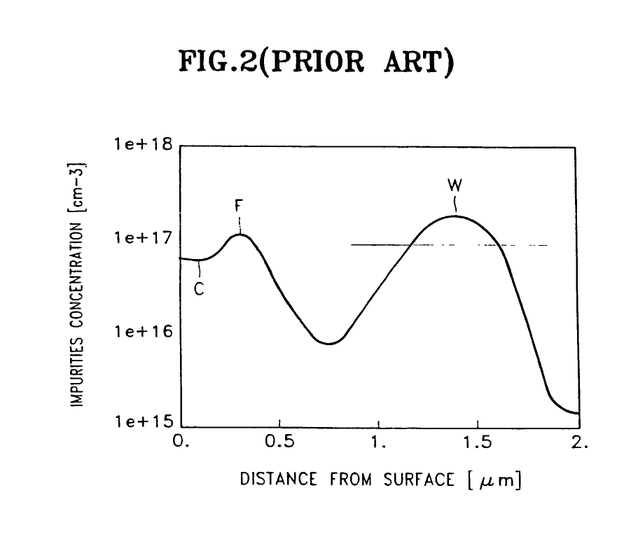

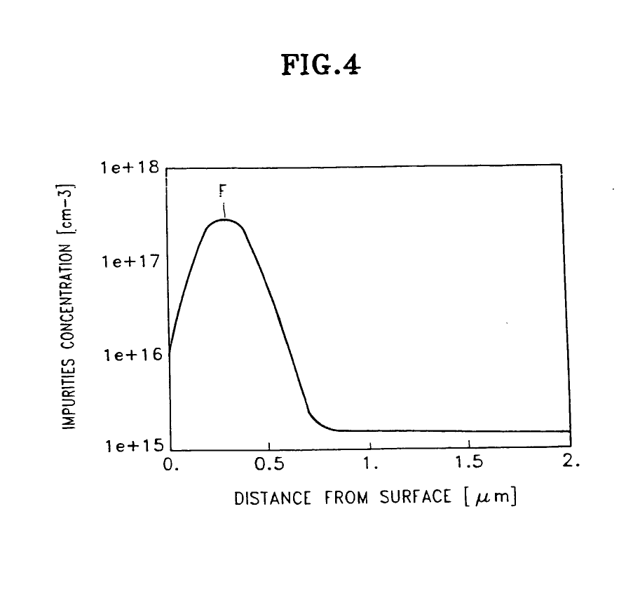

FIG. 4 is a vertical doping density profile of a well through one-dimensional simulation, after performing the P-field ion-implantation process. A conventional retrograde well has two peaks as shown in FIG. 2, but a well according to the present invention has one peak. The depth, d, of a conventional retrograde well 24 (FIG. 1C) is approxiamtely 2 μm, while the depth, D, of an improved well 34 (FIG. 3B) can be formed to a thinness of 1 μm or less. Therefore, a high-energy well ion-implantation process of approximately 800 KeV and an additional ion-implantation for punchthrough stop can be eliminated.

A channel ion-implantation process can for controlling the transistor voltage Vₜₕ can be added to N-well 34 where a p-channel MOS transistor is to be formed. Each process condition is determined in accordance with the characteristics of the unit device.

FIG. 3C shows a step of forming P-well 44 where an n-channel MOS transistor is to be formed. A photoresist is coatded on the whole surface of substrate 30, after eliminating first photoresist pattern 33, and then exposed and developed, thereby forming a second photoresist pattern 43 on the substrate wherein the N-well is formed. Here, second photoresist pattern 43 is formed thick as to prevent penetration into N-well 34 in the ion-implantation for forming a P-well.

P-well 44 having a junction depth of less than 1.0 μm can be formed by performing an N-field ion-implantation with boron, for example, at an energy level of 140 KeV at a concentration of 3.5E12 ions/cm₂ using the mask mask of the second photoresist pattern 43 P-type impurities, going through a high-energy ion-implantation process for retrograde well peak. To control the threshold voltage of an N-MOS transistor, boron fluoride (BF₂) under the conditions of 40˜60 KeV and 1.0E12/cm² can be ion implanted.

FIG. 3D shows a step of respectively forming a p-channel MOS transistor and an n-channel MOS transistor on N-well 34 and P-well 44, respectively. After eliminating second photoresist pattern 43, gate oxide film 35 and gate polysilicon 37 are formed by using a photographic etching process Then p⁺ source/drain region 39 of P-MOS and n⁺ source/drain region 49 of N-MOS are formed, respectively. the succeeding processes are performed in the same manner as that performed in a conventional CMOS process.

The well ion-implantation process can be skipped in the above embodiment regardless of conductivity types, but can be used according to the various types of transistor to be made.

Accordingly, in forming N-well 34 having a conductivity type opposite substrate 30, a retrograde N-well is formed by first high-energy ion-implantation of 800 KeV at a dosage of 1.0E13/cm², subsequently by a second ion-implantation of 300 KeV and 5.0E12/cm², The first ion-implantation is performed so as to control the peak concentration of the well and the second is performed so as to achieve the function of a channel stopper in an isolated region. In forming P-well 44 having the same conductivity type as that of substrate 30, the electrical characteristics of the device can be obtained by optimizing the conditions of the N-field ion-implantation without going through a high-energy well ion-implantation process.

However, these processes can be performed by skipping only the N-well ion-implantation process. A person skilled in the art can understand that this can be applied to not only a CMOS but also to a unit device.

Tests concerning the reliability of the method for forming a well according to the present invention shows the following results.

First, optimization can be obtained by splitting the field ion-implantation process. With the elimination of the P-well ion-implantation process, optimization is achieved by selecting the N-field ion-implantation according to the threshold voltage of the N-MOS and results from comparing and analyzing the threshold voltage, device isolation, and punchthrough characteristics between a P-MOS produced by splitting the P-field ion-implantation process conditions due to the N-well skipping and a P-MOS produced by a method of a normal retrograde well formation.

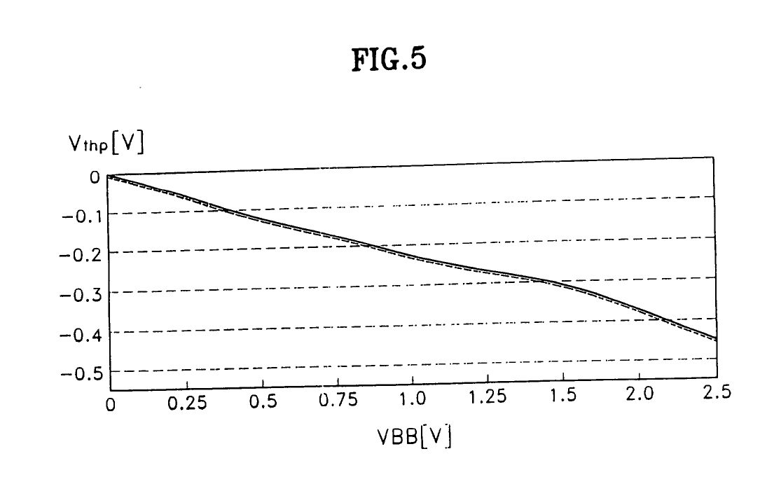

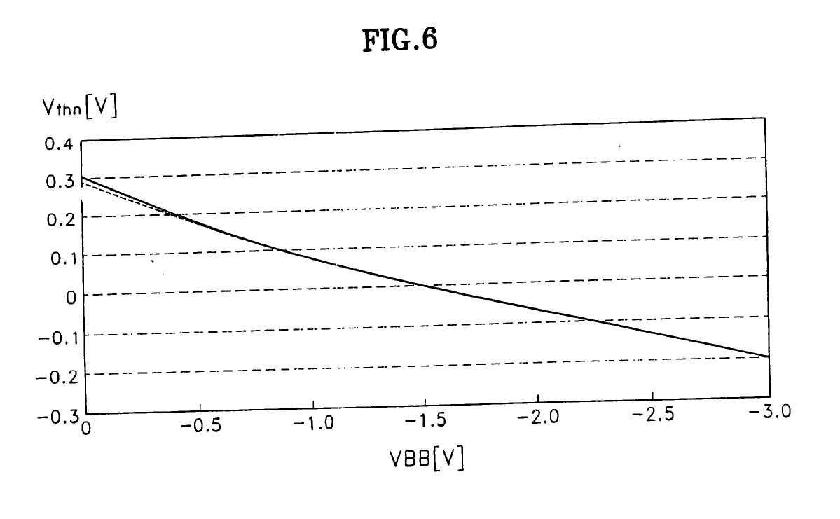

The reliability of the electrical characteristics of devices with wells produced by a conventional method and the method according to the present invention, respectively, can be shown in FIGS. 5 and 6, which are graphs summarizing the measured body effect. The body effect is an indication of the change in the threshold voltage, Vₜₕ, according to varying back bias voltages V_{BB} supplied to the substrate, the change of the back bias voltage V_{BB} simplifies control of the threshold voltage of the transistor and reduces contact capacitance, thereby monitoring the operation characteristics of a device. FIG. 5 shows an analysis of the body effect of splitting the P-MOS transistors according to back bias voltage V_{BB}, in which the solid line indicates the characteristics of a transistor according to a conventional method and the dotted line according to the present invention. FIG. 6 shows the body effect on an N-MOS transistor.

As shown in FIGS. 5 and 6, the present invention shows almost the same result as that of a conventional method. Accordingly, it shows that the change of bulk concentration in skipping a high-energy well ion-implantation process has little effect on the characteristics of a unit device on the silicon surface.

In Table 1 the latchup characteristics are shown for different process conditions, wherein group A eliminates the P-well ion-implantation process, group B shows a conventional method of retrograde well formation and group C eliminates both ion-implantation processes of the N-well and the P-well.

TABLE 1

| | LATCHUP | |
|---|---|---|
| GROUP | CHARACTERISTICS | REMARKS |
| A | 9.13 V | P-well skip |
| B | 9.07 V | normal |
| C | 8.77 V | N-, P-well skip |

As shown in Table 1, the difference according to split is hardly noticeable and the latchup characteristics can be stabilized by optimizing the field ion implatation process condition according to the elimination of well ion-implantation.

Accordingly, proper control of the process condition for optimizing the electrical characteristics of a device ensures stabile reliability.

Therefore, the method for forming a well according to the present invention simplifies processes and enhances production without lowering the operational characteristics and reliability of a semiconductor device.

The present invention is not limited to the above examples and many other variations may be available to those skilled in this art.

What is claimed is:

1. A method for forming wells in a high integration semiconductor device, wherein said wells for forming transistors of a predetermined conductivity type in said semiconductor device are formed by a field ion-implantation process performing functions of both a punchthrough stopper and a channel stopper while skipping a high-energy well ion-implantation process.

2. A method for forming wells in a high integration semiconductor device, wherein P-wells for forming an n-channel transistor are formed, omitting a high-energy well ion-implantation process, by a field ion-implantation process performing functions of both a punchthrough stopper and a channel stopper and forming a well region within a depth of approximately 1.0 μm.

3. A method for forming wells in a high integration semiconductor device, wherein N-wells for forming a p-channel transistor are formed, omitting a high-energy well ion-implantation process, by a field ion-implantation process performing both functions of a punchthrough stopper and a channel stopper and forming a well region within a depth of approximately 1.0 μm.

4. A method for forming wells in a CMOS integrated circuit device comprising the steps of:
preparing a semiconductor substrate of a second conductivity type;
forming a field oxide film for defining an active region on said semiconductor substrate;
forming a mask pattern on the active region of one side isolated by said field oxide film;
forming a well of a first conductivity type, wherein a field ion-implantation process is performed at a selected ion-implantation energy and using a selected dose for performing functions of both a punchthrough stopper and a channel stopper without lowering latchup characteristics on the whole surface of said exposed semiconductor substrate, to form a transistor having the same conductivity type channel as said substrate; and
forming a well of a second conductivity type, wherein a field ion-implantation process is performed by a mask having a pattern opposite said mask at a selected ion-implantation energy, with a selected dose, at a selected dopant, to form a transistor having a channel of a conductivity type opposite said substrate.

5. A method for forming wells according to claim 4, wherein said semiconductor substrate is made of silicon with orientation (100), impurities of said first conductivity type is selected from a group consisting of phosphorus and arsenic, and the impurities of said second conductivity type is boron.

6. A method for forming wells according to claim 4, wherein a region of the well of said first conductivity type is formed within a depth of approximately 1.0 μm.

7. A method for forming wells according to claim 4, wherein a field ion-implantation process is performed at an energy level of approximately 350˜400 KeV and the concentration of the dosage is between 7.0E12˜1.0E13/cm².

8. A method for forming wells according to claim 6, wherein a field ion-implantation process is performed at an energy level of approximately 350˜400 KeV and the concentration of the dosage is between 7.0E12˜1.0E13/cm².

9. A method for forming wells according to claim 4, wherein a well region of said second conductivity type has a depth of approximately 1.0 μm or less.

10. A method for forming wells according to claim 4, wherein a field ion-implantation process is performed at an energy level of approximately 110˜160 KeV and the concentration at the dosage is between 3.0E12˜5.0E12/cm².

11. A method for forming wells according to claim 9, wherein a field ion-implantation process is performed at an energy level of approximately 110˜160 KeV and the concentration at the dosage is between 3.0E12˜5.0E12/cm².

12. A method for forming wells according to claim 4, wherein a channel ion-implantation process for controlling the threshold voltage of a transistor is performed in addition, to the formation process of the well of said first conductivity type.

13. A method for forming wells according to claim 4, wherein a channel ion-implantation process for controlling the threshold voltage of a transistor is performed in addition, to the formation process of the well of said second conductivity type.
